(19) United States
(12) Patent Application Publication
(10) Pub. No.: US 2008/0261401 A1
(43) Pub. Date: Oct. 23, 2008

(54) Chemical-Mechanical Polishing of Sic Surfaces Using Hydrogen Peroxide or Ozonated Water Solutions in Combination with Colloidal Abrasive

(75) Inventors: Thomas M. Kerr, Oxnard, CA (US); Christopher T. Martin, Bloomfield, NJ (US); Walter R. Stepko, Piscataway, NJ (US); Thomas E. Anderson, Convent Station, NJ (US)

Correspondence Address: THE WEBB LAW FIRM, P.C., 700 KOPPERS BUILDING, 436 SEVENTH AVENUE, PITTSBURGH, PA, 15219, US

(73) Assignee: II-VI INCORPORATED, SAXONBURG, PA (US)

(21) Appl. No.: 11/547,370

(22) PCT Filed: Apr. 6, 2005
(86) PCT No.: PCT/US2005/011693

§ 371 Date: Sep. 6, 2007

Related U.S. Application Data
(60) Provisional application No. 60/560,488, filed on Apr. 8, 2004.

(51) Int. Cl. H01L 21/461; B24B 1/00; B24B 29/00

(52) U.S. Cl. 438/693; 451/36; 451/41; 451/53; 257/E21.483

(57) ABSTRACT

A process is taught for producing a smooth, damage-free surface on a SiC wafer, suitable for subsequent epitaxial film growth or ion implantation and semiconductor device fabrication. The process uses certain oxygenated solutions in combination with a colloidal abrasive in order to remove material from the wafer surface in a controlled manner. Hydrogen peroxide with or without ozonated water, in combination with colloidal silica or alumina (or alternatively, in combination with HF to affect the oxide removal) is the preferred embodiment of the invention. The invention also provides a means to monitor the sub-surface damage depth and extent since it initially reveals this damage though the higher oxidation rate and the associated higher removal rate.

### BACKGROUND OF THE INVENTION

1. Field of the Invention

The present invention relates to the creation, by chemical-mechanical polishing, of damage-free SiC semiconductor wafer surfaces which are suitable for further epitaxial film growth, ion implantation, and/or subsequent device processing.

2. Description of Related Art

SiC is a semiconductor material with a unique combination of electrical and thermo-physical properties that make it extremely attractive and useful for electronic devices. These properties which include, for example, high breakdown field strength, high practical operating temperature, good electronic mobility and high thermal conductivity, make possible device operation at significantly higher power, higher temperature and with more radiation resistance than comparable devices made from the more conventional semiconductors, silicon and GaAs. It is estimated that transistors fabricated from high resistivity “semi-insulating” SiC will produce over five times the power density of comparable GaAs microwave integrated circuits at frequencies up to 10 GHz.

In addition to microwave devices, SiC substrates are used to fabricate power switching devices and diodes whose high voltage and current handling characteristics are 5-10 times greater than comparable silicon-based devices, and which are forecast to reduce significantly the device power losses in utility applications. SiC transistors can operate at temperatures of 400-500° C. versus 100-150° C. for silicon devices, making possible electronics for environmentally hostile applications, such as nuclear reactors, aircraft engines, and oil well logging.

In addition, semi-insulating SiC is a preferred substrate for the growth of GaN-based films which can be fabricated into microwave transistors and circuits that operate at even higher microwave frequencies than possible with SiC-based devices. Conductive SiC substrates are used to fabricate GaN-based light-emitting diodes for traffic control, displays and automotive applications.

As is well known in the semiconductor art, the abrasive lapping and polishing processes used to produce planar wafers may leave residual surface damage and defects which adversely affect subsequent device production steps. Epitaxial films formed on such surfaces may develop localized defective regions, and device fabrication may exhibit excessively low yields. In addition, damaged surface material will affect the activation of dopants intentionally introduced into the surface during any ion implantation step used during device manufacture.

The sub-surface damage is difficult to see optically and is normally revealed by etching, e.g., in the specific case of SiC, by molten KOH etching. This method is destructive since it renders the surface rough and enhances defects that are present from the SiC growth process. The damage may be evident after thermal processing in an epitaxial reactor prior to the epitaxy and is normally enhanced after epitaxy by defect delineation on top of the damage. This normally manifests itself as a dense scratch network, corresponding to the abrasive path of slurry particles over the surface during previous polishing steps.

Chemical-mechanical polishing (CMP) treatments using colloidal silica and various etch chemistries have been evolved to maximize stock removal and minimize surface damage in wafers of silicon. In silicon CMP, material removal has been shown to increase by buffering up the pH of the colloidal silica (i.e., with increasing OH⁻ concentration) either with NH₄OH solution or with KOH solution. However, the significantly greater hardness and relative chemical inertness of SiC, particularly the oxidation of carbon, has made the development of an analogous chemical-mechanical polishing process difficult. Neither buffered colloidal slurries (higher pH) nor other commercially available colloidal slurries with other oxidizing agents (e.g., sodium hypochlorite or tri-chloro-iso cyanuric acid) seems to work on SiC.

Current SiC chemical-mechanical processes are irreproducible or at best slow and expensive. As a result, the full value of SiC's unique semiconductor properties may not be realized in practice.

### SUMMARY OF THE INVENTION

The objective of this invention is to provide a process to produce smooth, damage-free silicon carbide substrates with uniform electrical properties and structural quality suitable for epitaxial film growth, ion implantation, and/or device fabrication with a chemical mechanical polish process that circumvents the problems and difficulties of prior art.

The invention meets this objective with a process that chemically-mechanically removes material from SiC, using standard polishing equipment (SiC wafer carrier and polishing element), and achieves a damage-free, highly polished surface. The main embodiment of the process uses the added oxidation agents hydrogen peroxide and/or ozonated water (either separately or in combination) to a suspension of colloidal silica or alumina onto the polishing element (pad or plate) upon which SiC material is polished. The degree of “ozonation” of the water (i.e., the amount of dissolved ozone in solution) or the degree of concentration of the hydrogen peroxide may be adjusted in order to control the rate of oxidation of the silicon carbide and, therefore, the removal rate of SiC from the surface. The colloidal silica may be buffered up to a pH in the range 8-14 in order to further enhance the oxidation rate of SiC. The colloidal suspension may have silica or alumina particles, or both, with sizes in the region up to 300 nm in the final step(s) of the process. However, previous steps are envisioned with larger particle sizes or indeed using sub-micron diamond slurry in order to achieve low damage “stock” removal in so-called lapping/intermediate-polishing steps. Polishing of SiC with KOH or NH₄OH buffered (pH 8-14) colloidal silica or alumina alone is also covered by the present invention.

In a further embodiment of the process, improvements can be gained by increasing the process temperature. Raising the temperature can be achieved in two ways. The polishing slurries, wafer carrier, wafers and the polishing plate can be heated directly to a higher temperature or the temperature can be raised using a chemical reaction. In the latter case an acidic or basic solution such as sulfuric acid (H₂SO₄) or potassium hydroxide (KOH) or ammonium hydroxide (NH₄OH) may be added to the process in order to stimulate an exothermic reaction, which ultimately raises the temperature at the wafer surface. It is envisioned that this increase in temperature will aid the removal of SiC into solution.

A purely chemical process (that is without the colloidal silica or alumina) is also provided whereby the oxides of SiC, created as described above, are removed by purely chemical reduction in agents such as HF.

### BRIEF DESCRIPTION OF THE DRAWINGS

FIG. 1 is a graph showing the roughness of a SiC wafer during processing as a function of time; and

FIG. 2 are photographs showing the surface morphology of various SiC wafer samples.

### DETAILED DESCRIPTION OF THE PREFERRED EMBODIMENT

An important feature of the process taught here lies in the method of oxidation of the surface of a SiC wafer by hydrogen peroxide and/or ozonated water, either separately or in combination. The removal of the oxide is accomplished by the abrasive friction of colloidal silica or alumina or by purely chemical reduction of the oxides in agents, such as HF, without damaging the SiC surface. When used separately or in combination these agents lead to a very planar, extremely low roughness surface (for example, <<3 Angstrom units measured by a Zygo white light interferometry, over a 350 um×250 um field of view, or <0.5 Angstrom units measured by atomic force microscopy (AFM) in a 5×5 um field of view). The resulting surface is also sub-surface damage free.

The state of the art of SiC polishing elsewhere produces a wafer surface which has a much higher level of surface roughness (3-15 Angstroms) and has evidence of some degree of sub-surface damage. State-of-the-art removal rates with conventional chemical-mechanical processes are also low. The combination of low surface roughness and zero sub-surface damage achieved by the present invention is not available from any existing polishing operation. The process of the present invention achieves these results without a large degree of etching or polishing selectivity, which ensures that any growth defects or stochiometry variations in the SiC crystal are not overly etched, enhanced or preferred. The process is able to remove sub-surface damage from SiC crystals of every orientation, including Si terminated or C-terminated (0001) exactly oriented crystals.

Surfaces are vital to customers who perform epitaxy on SiC since the overgrowth will decorate any damaged areas or rough surfaces and lead to poor interface control, rough interfaces and carrier scattering, which will degrade transport properties and performance of subsequently produced devices. In addition, customers performing ion implantation should see better implant activations and lower surface and sub-surface intrinsic trap levels and, therefore, improved device performance. Schottky diode or MOS devices made directly on top of low roughness, “sub-surface damage free” material will have improved characteristics.

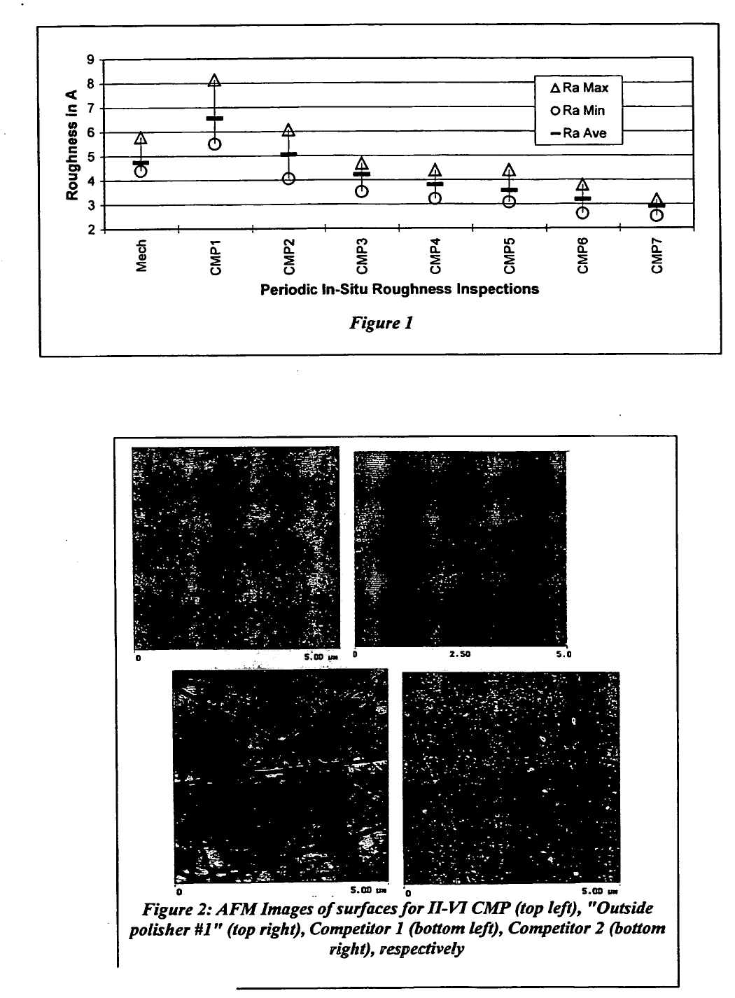

The oxidation process of the present invention is also an efficient method to reveal all levels of sub-surface damage and dislocations that are normally invisible by most optical techniques. The efficient oxidation process, using H₂O₂ (hydrogen peroxide) or ozonated water, acts faster on dislocated and damaged material compared to undamaged material. Thick, oxidized material is easy to discriminate by optical methods and easier to remove by abrasive friction or reduction. The combination of the oxidation and the polishing process can be used to monitor the degree of damage and the removal of damage as a function of time throughout the process, as illustrated in FIG. 1. This figure shows that the average roughness (Ra) increases initially as the damage is decorated and revealed, then eventually falls as the damaged, oxidized material is selectively removed. Since the oxidation process is ongoing, the lack of appearance of new features and the leveling off of roughness is a good indication of absence of sub-surface damage.

In addition, the contemplated methods of using higher temperatures could speed up the process. The proposal to use a purely chemical process (no colloidal silica or alumina abrasive) using ozonated water and/or hydrogen peroxide (separately or in combination) as the oxidizing agents and HF to affect the oxide removal is also unique.

We have demonstrated sub-surface damage removal using the present invention as well as attained very low surface roughness. This is evidenced by studies of the surfaces using optical interferometry and microscopy.

Sub-surface damage removal and roughness improvement is also demonstrated in FIG. 1, which shows the evolution of the surface roughness as a function of timed steps in the process, from an initial mechanical polish (Mech) and subsequently inspected through periodic intervals of polishing according to the present invention (CMP1 through CMP7). Ultimate roughness levels of <2 A by optical interferometry have been demonstrated. Sub-surface damage free material after this process has been demonstrated using molten KOH etching, which delineates sub-surface damage, if present. The surface after KOH etching shows no sub-surface scratch network which would be indicative of sub-surface damage. The features observed microscopically are growth related dislocations, which have been revealed by the etching.

Excellent planarity and micro-roughness has been demonstrated from the process as evidenced using Zygo white light interferometry. We have bench marked the process against the acknowledged best external polisher for SiC as well as the largest SiC commercial wafer vendors and found the process of the present invention to be superior in all roughness aspects. This is illustrated in tables 1 and 2 below.

TABLE 1
Roughness Figures of merit from the various suppliers.

| | | | | | # | # |
|---|---|---|---|---|---|---|
| Supplier | Max | Min | Average | STDEV | Wafers | Measurements |
| Present | 4.8 | 1.8 | 3.3 | 0.9 | 40 | 100 |
| Invention | | | | | | |
| Outside | 13.8 | 3.1 | 5.8 | 2.0 | 42 | 65 |
| Polish #1 | | | | | | |
| Competitor 1 | 15.6 | 8.8 | 10.7 | 2.9 | 10 | 20 |
| Competitor 2 | 9.3 | 1.3 | 4.3 | 3.7 | 10 | 20 |

It is clear that the chemical-mechanical polishing (CMP) method of the present invention yields a much better roughness than state-of-the-art substrate suppliers. The distribution of the data is also tighter. More importantly, the data relating to the present invention is superior in roughness terms to the CMP finish of the acknowledged best commercial polish operation (“outside polish #1”). This is shown clearly in Table 2 where all of the followed roughness parameters shown are superior for the present invention. In this table the parameter PV is the max to min roughness, the parameter Ra is the average roughness and the parameter H is the Swedish height, which removes the upper 5% and lower 10% of height features. The Swedish height is less sensitive to data spikes than PV.

TABLE 2
Roughness figures of merit for II-VI compared to the best
commercial polisher

| | Outside Polish 1 | | | Present Invention | | |
|---|---|---|---|---|---|---|
| Parameter | PV (A) | Ra (A) | H (A) | PV (A) | Ra (A) | H (A) |
| Average | 62.5 | 5.8 | 20.7 | 49.4 | 3.3 | 11.9 |
| Max | 106.8 | 13.8 | 48.2 | 83.6 | 4.8 | 17.7 |
| Min | 32.4 | 3.1 | 6.7 | 24.7 | 1.8 | 6.5 |
| Std dev | 16.7 | 2.0 | 7.1 | 13.9 | 0.9 | 3.2 |

Additionally, Atomic Force Microscopy measurements have shown the surface roughness of the present invention to be state-of-the-art. This is shown in Table 3 below. All the measurements were acquired using the Tapping Mode of a Digital Instrument AFM with a field of view of 5×5 μm. The mean roughness (Ra) is summarized in Table 3. The surface of a SiC wafer polished with the present invention was the smoothest among the four samples and had an Ra of 0.38 A. Competitor 1 was the roughest with a Ra of 11.2 A. The commercial polisher “outside polish #1” had a Ra of 0.94 A.

TABLE 3
AFM Roughness measurements on various surfaces from
different suppliers

| Supplier | Mean Roughness (Ra) |
|---|---|
| Present invention | 0.38 A |
| Outside polish #1 | 0.94 A |
| Competitor 1 | 11.20 A |
| Competitor 2 | 1.50 A |

The surface morphology of the four samples is shown in FIG. 2. There are no micro-scratches evident on wafer polished by the present invention. There are, however, two larger scratches in the “outside supplier #1” polished surface. The surface from the competitor 2's wafer has a large number of intersecting scratches. The wafer from competitor 1 has many deep and wide scratches, as reflected in the largest Ra among the four samples. Surfaces produced by the process of the present invention have been grown on by epitaxial techniques and found to have good morphology (i.e. free of scratch delineation which would indicate the presence of residual sub-surface damage).

Although the present invention has been described in detail in connection with the discussed embodiment, various modifications may be made by one of ordinary skill in the art without departing from the spirit and scope of the present invention. Therefore, the scope of the present invention should be determined by the attached claims.

We claim:

1. A method for producing a smooth, planar, damage-free surface on a SiC wafer, suitable for subsequent epitaxial film growth, ion implantation, semiconductor device fabrication, or other uses, said method comprising the steps of:
a) providing a suspension of a colloidal abrasive;
b) adding an oxidation agent to the colloidal abrasive suspension, thereby forming a polishing slurry;
c) attaching the SiC wafer to a carrier and positioning the carrier such that a surface of the SiC wafer is against a surface of a polishing element, such as a pad or plate;
d) placing the polishing slurry on the surface of the polishing element in contact with the SiC wafer; and
e) moving the wafer and/or the polishing element with respect to each other whereby the polishing element and the polishing slurry remove material from and thereby polish the surface of the SiC wafer in a controlled manner.

2. The method of claim 1 wherein the colloidal abrasive suspension includes colloidal silica and/or colloidal alumina.

3. The method of claim 1 wherein the oxidation agent includes hydrogen peroxide and/or ozonated water.

4. The method of claim 3 further including the step of controlling the degree of concentration of the hydrogen peroxide and/or controlling the degree of ozonation of the ozonated water to control the rate of oxidation of the SiC wafer.

5. The method of claim 1 further including the step of buffering the pH of the colloidal abrasive suspension in the range of 8-14 to enhance the oxidation rate of the SiC wafer.

6. The method of claim 1 further including the step of increasing the temperature of operation during step e).

7. The method of claim 6 wherein the temperature is increased by heating one or more of the elements or materials, including the SiC wafer, the carrier, the polishing element and/or the polishing slurry.

8. The method of claim 6 wherein the temperature is increased by increasing the temperature of the polishing slurry through a chemical reaction.

9. The method of claim 8 further including adding an acidic or basic solution to the polishing slurry so as to stimulate an exothermic reaction.

10. The method of claim 9 wherein the added solution includes sulfuric acid, potassium hydroxide or ammonium hydroxide.

11. The method of claim 1 wherein the colloidal abrasive suspension has abrasive particles therein up to 300 nm in size in later or finishing polishing steps.

12. The method of claim 11 further including a lapping/intermediate polishing operation, prior to the steps set forth in claim 1, wherein a sub-micron diamond slurry is used as the polishing slurry.

13. A method for producing a smooth, planar, damage-free surface on a SiC wafer, suitable for subsequent epitaxial film growth, ion implantation, semiconductor device fabrication, or other uses, said method comprising the steps of:
a) providing a suspension of a colloidal abrasive;
b) buffering the colloidal abrasive suspension to a pH of 8-14 to form a polishing slurry;
c) attaching the SiC wafer to a carrier and positioning the carrier such that a surface of the SiC wafer is against a surface of a polishing element, such as a pad or plate;
d) placing the polishing slurry on the surface of the polishing element in contact with the SiC wafer, and
e) moving the wafer and/or the polishing element with respect to each other whereby the polishing element and the polishing slurry remove material from and, thereby polish the surface of the SiC wafer in a controlled manner.

14. The method of claim 13 wherein the colloidal abrasive suspension is buffered with potassium hydroxide or ammonium hydroxide.

15. The method of claim 13 wherein the colloidal abrasive suspension includes colloidal silica and/or colloidal alumina.

16. The method of claim 13 further including the step of increasing the temperature of operation during step e).

17. The method of claim 16 wherein the temperature is increased by heating one or more of the elements or materials, including the SiC wafer, the carrier, the polishing element and/or the polishing slurry.

18. The method of claim 16 wherein the temperature is increased by increasing the temperature of the polishing slurry through a chemical reaction.

19. A method for producing a smooth, planar, damage-free surface on a SiC wafer, suitable for subsequent epitaxial film growth, ion implantation, semiconductor device fabrication, or other uses, said method comprising the steps of:
a) combining a chemical reduction agent, such as HF, with an oxidation agent, such as hydrogen peroxide and/or ozonated water, to form a polishing slurry;
b) attaching the SiC wafer to a carrier and positioning the carrier such that a surface of the SiC wafer is against a surface of a polishing element, such as a pad or plate;
c) placing the polishing slurry on the surface of the polishing element in contact with the SiC wafer; and
d) moving the wafer and/or the polishing element with respect to each other whereby the polishing element and the polishing slurry remove material from and, thereby polish the surface of the SiC wafer in a controlled manner.

20. The method of claim 19 further including the step of controlling the degree of concentration of the hydrogen peroxide an/or controlling the degree of ozonation of the ozonated water to control the rate of oxidation of the SiC wafer.

21. The method of claim 19 further including the step of increasing the temperature of operation during step d).

22. The method of claim 21 wherein the temperature is increased by heating one or more of the elements or materials, including the SiC wafer, the carrier, the polishing element and/or the polishing slurry.

23. The method of claim 21 wherein the temperature is increased by increasing the temperature of the polishing slurry through a chemical reaction.

24. The method of claim 23 further including adding an acidic or basic solution to the polishing slurry so as to stimulate an exothermic reaction.

25. The method of claim 24 wherein the added solution includes sulfuric acid, potassium hydroxide or ammonium hydroxide.
